(19) United States
(12) Patent Application Publication
(10) Pub. No.: US 2023/0195951 A1
(43) Pub. Date: Jun. 22, 2023

(54) Computerized method of composing a system for performing a Task

(71) Applicant: City University of Hong Kong, Hong Kong (CN)

(72) Inventors: Kening ZHU, Hong Kong (CN); Taizhou CHEN, Hong Kong (CN); Lantian XU, Hong Kong (CN)

(21) Appl. No.: 17/644,662

(22) Filed: Dec. 16, 2021

(51) Int. Cl. G06F 30/12; G06F 40/40; G06F 40/279; G06F 8/34

(52) U.S. Cl. CPC G06F 30/12; G06F 40/40; G06F 40/279; G06F 8/34

(57) ABSTRACT

Disclosed is a computer-implemented method of composing, using natural language processing, a system for performing a task. The method comprises receiving a user input comprising a sequence of words; processing the user input using a neural network for entity recognition to identify, from the sequence of words, a term defining an event; and searching a data store having stored therein data indicative of a plurality of components, using the identified term, to determine a component for the system.

### TECHNICAL FIELD

The present invention relates generally to a computerized method of composing a system for performing a task.

The invention has been developed primarily as a method of composing a physical computing system and will be described with reference to this application. However, it will be appreciated that the invention is not limited to this particular field of use.

### BACKGROUND

Physical-computing systems are used in various fields such as maker activities, STEM education, new media art, product design, or the like. Physical computing is known as the process of interacting with real world objects. A physical computing system typically comprises components for detecting parameters of the real-world objects, such as sensors, components for making interactive responses, such as lights, displays and motors, and a micro-controller. The process of developing a physical computing system usually begins with circuit design and micro-controller programming. Both require a high level of knowledge and skill in circuit design and programming.

Rapid-prototyping platforms, such as Arduino, BeagleBoard, Fritzing, etc., are known to support users with circuit design. Whilst these platforms have lowered the bar of entry for novice or inexperienced users, use of such platforms still requires some level of technical background, such as basic knowledge of electrical theory, understanding of components and the technical know-how thereof, and the like. Programming environments have also been developed to assist novice or inexperienced users with programming. For example, packages/libraries (e.g. Processing) and visual programming languages (e.g. Scratch) are known to have been developed to simplify the coding process. However, even with such programming platforms/languages, the coding process still requires a basic level of programming knowledge (e.g. syntax, storage, control flow, Boolean logic, etc.), which many designers, especially students, may not have.

Even for users who have a moderate level of technical background, constructing a circuit using the aforementioned tools is nonetheless a challenge. Circuit auto-completion tools, such as circuito.io, AutoFritz, etc., have been developed to further simplify the process of circuit design. However, the auto-completion function rests on the users determining the components to be used. For novice users who have come up with a high-level concept about what is to be achieved, it could be still challenging, without prior technical knowledge/experience, to determine the electronic components required to build the circuit. In addition, existing auto-completion tools do not assist with programming. Some have proposed to provide basic logical action blocks which can be dragged and dropped to assemble a circuit and code. Again, users are still required to have prerequisite knowledge of circuits and programming logic to use such logical action blocks.

It is an object of the present invention to substantially overcome or at least ameliorate one or more of the above disadvantages.

### SUMMARY

Disclosed are arrangements which seek to address the above problems by allowing a user to describe a system using natural language and performing natural language processing on the user input to generate a response for assisting the user to construct the system.

According to one aspect of the present disclosure, there is provided a computer-implemented method of composing, using natural language processing, a system for performing a task, the method comprising:

receiving a user input comprising a sequence of words;

processing the user input using a neural network for entity recognition to identify, from the sequence of words, a term defining an event; and

searching a data store having stored therein data indicative of a plurality of components, using the identified term, to determine a component for the system.

In some embodiments, the processing comprises identifying a further term defining a further event, and the searching comprises determining a further component for the system using the further term.

In some embodiments, the event and the further event have a causal relationship.

In some embodiments, the method further comprising generating a response based on the determined component.

In some embodiments, the response comprises a graphical representation of the system.

In some embodiments, the response comprises wiring instructions for guiding a user to physically construct the system.

In some embodiments, the response comprises a program code for running on a programming environment to configure the component.

In some embodiments, the computer-implemented method of claim 4, wherein the response comprises a program code for running on a programming environment to configure the system.

In some embodiments, the neural network comprises a Bidirectional Long Short-Term Memory (BiLSTM) layer.

In some embodiments, the neural network comprises a Conditional Random Fields (CRF) layer.

In some embodiments, the term is a verb before a noun.

In some embodiments, the term is a noun.

In some embodiments, the system is a physical computing system.

In some embodiments, the processing comprises identifying a further term defining an attribute of the event.

According to another aspect of the present disclosure, there is provided a computer program product including a computer readable medium having recorded thereon a computer program for implementing a method as described above.

According to another aspect of the present disclosure, there is provided a computer readable medium having recorded thereon a computer program for implementing a method as described above.

### BRIEF DESCRIPTION OF THE DRAWINGS

FIG. 1 is a schematic block diagram of an application for performing a method of composing a system for performing a task.

FIG. 2 is a block diagram showing further details and data flow of the application of FIG. 1.

FIG. 3 is an example lookup table having data storing thereon for component retrieval.

FIG. 4 is a flowchart of a method of composing a system for performing a task.

FIG. 5 is a flowchart of another method of composing a system for performing a task.

FIGS. 6A and 6B form a schematic block diagram of a general purpose computer system upon which arrangements described can be practiced.

FIG. 7 shows a use case of the application of FIG. 1.

### DETAILED DESCRIPTION

Where reference is made in any one or more of the accompanying drawings to steps and/or features, which have the same reference numerals, those steps and/or features have for the purposes of this description the same function(s) or operation(s), unless the contrary intention appears.

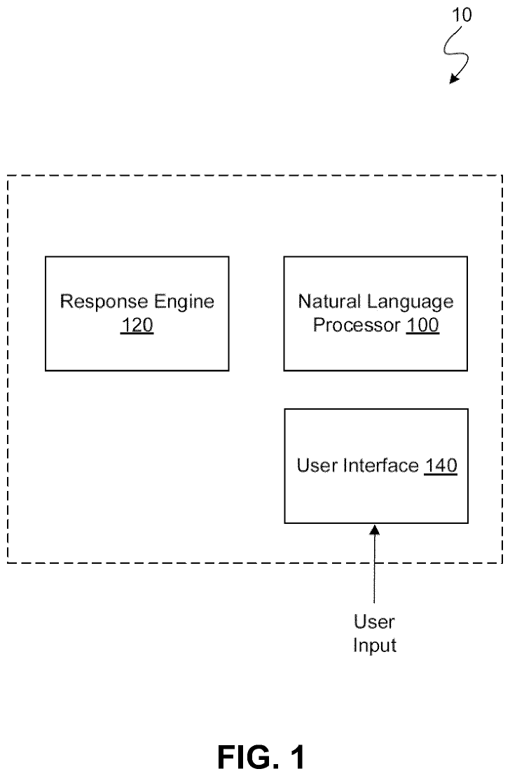

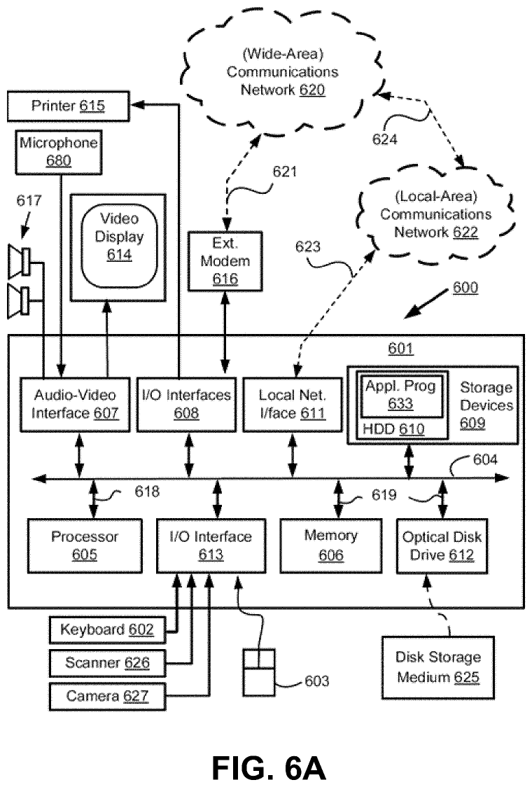

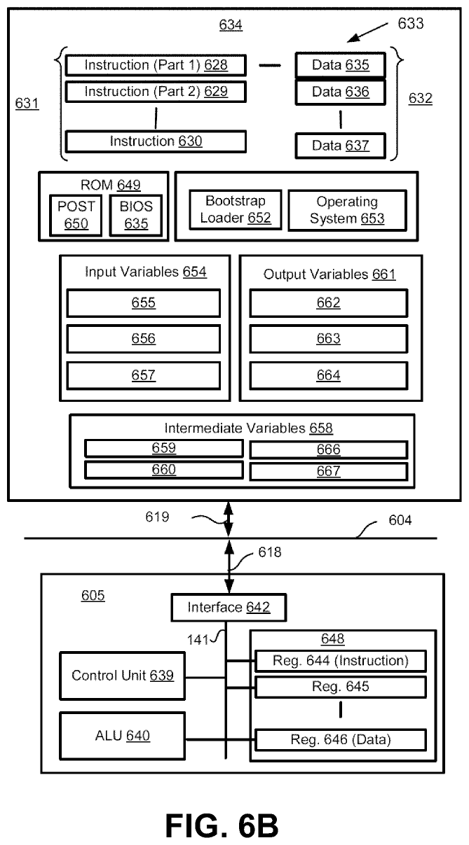

FIG. 1 shows a block diagram of an application 10 that implements a method, to be described, for composing a system for performing a task based on natural language user input. The application may operate on a general purpose computer system as discussed below with reference to FIGS. 6A and 6B. To compose a system, for example, a physical computing system, a user may input a description of an expected operation and a trigger of the operation using natural language to the application 10. In another example, the user may input a general query about how to use a particular electronic component.

The user input is in the form of textual data. The textual user input may be obtained via a keyboard, converted from a voice command input via a microphone, or otherwise obtained. In some embodiments, the application 10 is in data communication with external programs. For instance, the application 10 may be in data communication with a circuit simulator program such as Fritzing via Application Programming Interface (API). In some embodiments, the application 10 is implemented as a plug-in or add-on of the circuit simulator program. In such implementations, the application 10 can obtain the user input via a user interface of the circuit stimulator program and otherwise exchange data with the circuit stimulator program. For instance, the application 10 may transmit instructions to the circuit stimulator program which cause the circuit stimulator program to perform a function. However, it will be appreciated that the application 10 may also be a stand-alone application or adapted to be used with other circuit simulator programs. Additionally or alternatively, the application 10 may load data to electronic prototyping platforms such as Arduino via an interface.

The application 10 comprises a natural language processor 100 for interpreting the user input and a response engine 120 for generating a proper response to the user based on the interpretation.

The user may interact with the application 10 via a user interface 140. The user interface exchanges data with the natural language processor 100 using a communication protocol such as TCP/IP or the like. The user interface 140 may be implemented as a part of the user interface of the circuit simulator program.

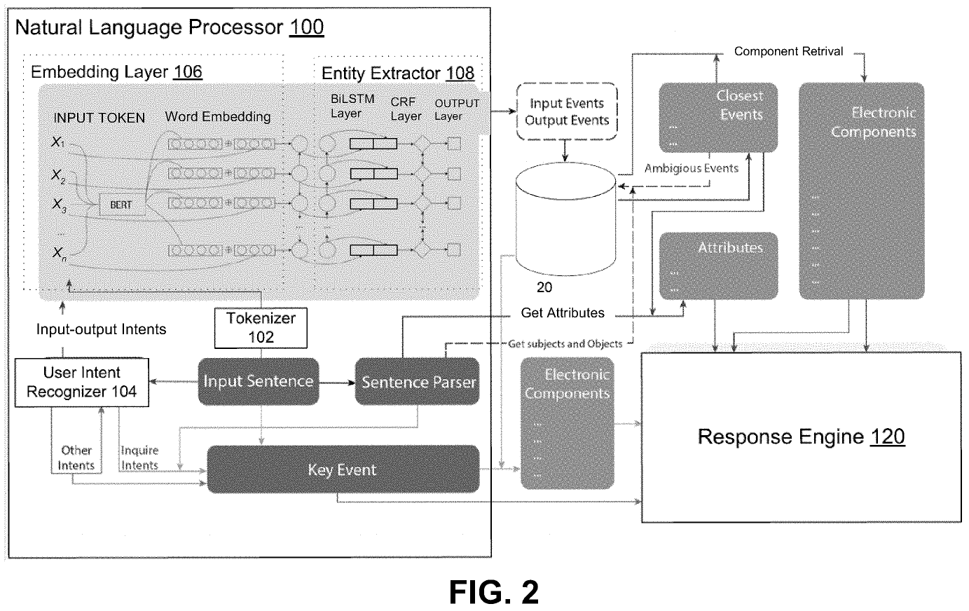

Referring to FIG. 2, a block diagram illustrating further details and data flow of the application 10 is shown. The natural language processor 100 comprises a tokenizer 102, a user intent recognizer 104, an embedding layer 106, and an entity extractor 108. The tokenizer 102 converts the textual user input to a sequence of words (i.e., tokens). The user intent recognizer 104 recognizes the user intent. For example, the user intent recognizer 104 may distinguish between a query about a specific electronic component and an intent to construct a system. The user intent recognizer 104 may be Dialogflow. It will be appreciated that other technologies such as marsview.ai, IBM Watson, or the like may also be used to recognize user's intent in some implementations. The embedding layer 106 is able to convert tokens to vector representations. In the example of FIG. 2, the embedding layer 106 computes a Part-of-Speech (POS) tags vector and a word vector and concatenates the vectors to form a vector representation for each word. The POS tags may be generated by a POS tagger such as Natural Language Toolkit (NLTK). The word vector can be generated by, for example, a pre-trained Bidirectional Encoder Representations from Transformers (BERT) model. Other vectorization techniques such as Skip-gram, CBOW, or the like may also be used to represent textual user input in vector space.

The application 10 is in data communication with a data store 20. The data store 20 may be an element of or accessible by the application 10. The data store may be a database comprising a number of tables and a number of records for various forms of data that are stored.

The entity extractor 108 employs a neural network to interpret the user input. The inventors have determined that novice users such as students often describe a physical-computer task using a causal relationship, for instance, in the form of a cause (i.e., trigger) and an effect (i.e., operation). Causes/triggers and effects/operations are collectively referred to as events hereinafter. For instance, a student of an undergraduate physical-computing course envisioned a physical computing system to perform the following task:
“When the user swings the baton, a bird will sing a song.”

However, novice users tend to lack the knowledge and experience to map the expected trigger (e.g., user swings the baton) and operation (e.g., sing a song) to electronic components required to build the system. The neural network according to the present invention is therefore trained or otherwise configured to recognize cause/trigger entities and effect/operation entities from a sentence.

Sequence labeling (also referred to as sequence tagging) is known to be used to perform entity recognition tasks. However, most existing models for sequence labelling are based on linear statistical models, such as Hidden Markov Models (HMMs) and conditional random fields (CRFs). With the emerging technology of deep learning, recurrent neural networks (RNNs) were designed to process sequential data. However, the RNN architecture can only capture dependencies on the most recent inputs in a sequence (e.g., neighboring words) and therefore is limited to capturing short range dependencies. Long Short-term Memory Network (LSTM) and Bidirectional LSTM (BiLSTM) were designed to capture long range dependencies in data sequence. In particular, the BiLSTM model considers both past features (i.e., previous few words) and future features (i.e., next few words) in the sequence and has proved to outperform traditional RNNs architecture in video processing, sketch encoding, and sensor signal processing. Accordingly, the BiLSTM model is suitable for performing sequence labelling tasks, more particularly named-entity recognition tasks, which rely highly on both past features and future features. Combining BiLSTM and CRF models has proved to perform well on named-entity recognition tasks.

The neural network according to the present invention employs a BiLSTM-CRF model to label the user input. The BiLSTM-CRF model has a structure of a concatenation of a BiLSTM layer and a CRF layer, as shown in FIG. 2. In natural language processing and understanding, it is important to understand the context of each token. For example, words following a subordinating conjunction (such as when, if, before, or the like) that specify a time or condition are likely to be describing a trigger of an operation. Accordingly, it is beneficial to apply a CRF layer to the output of the BiLSTM layer to encode the feature of the neighbor tag in predicting the current tag, thereby selecting the best predicted sequence.

The BiLSTM layer uses a BiLSTM model defined by the following equations:

i₁=σ(Wₓᵢxᵢ+Wₕᵢhₜ₋₁+W_{ci}cₜ₋₁+bᵢ)

fₜ=σ(W_{xf}xₜ+W_{hf}hₜ₋₁+W_{cf}cₜ₋₁+b_{f})

cₜ=fₜcₜ₋₁+iₜ tanh(W_{xc}xₜ+W_{hc}hₜ₋₁+b_{c})

oₜ=σ(Wₓₒxₜ+Wₕₒhₜ₋₁+W_{co}cₜ+bₒ)

hₜ=oₜ tanh(cₜ)

where σ is the sigmoid function, xₜ is the t^{th} word in an input sentence X=(x1, x2, x3 . . . , xn) containing a sequence of n words, i, f, c and o denote input gate, forget gate, cell state, and output gate, respectively, b denotes the bias for each gate, and hₜ denotes the hidden vector that is output at each time step and passed to the next LSTM cell. W denotes the weight matrix. For example, Wₕᵢ denotes the weight matrix for computing input gate based on the hidden vector. W_{xf} denotes the weight matrix for computing the forget gate based on xₜ, etc.

Using the above BiLSTM model, the BiLSTM layer computes a first feature vector representation [symbol] for each word in a forward direction and a second feature vector representation [symbol] for each word in a backward direction. A concatenation of the first and second representations h=[ [symbol] ; [symbol] ] for each word is then fed into the CRF layer.

In the CRF layer, a score is computed for an input sequence X=(x₁, x₂, x₃ . . . xₙ) and a sequence of prediction Y=(y₁, y₂, y₃ . . . , yₙ) thereof, as defined by the following equation:

$$score ( X , Y ) = {{\sum }_{i = 0}}^{n} {A}_{{y}_{i} {y}_{i + 1}} + {{\sum }_{i = 1}}^{n} {h}_{i , {y}_{i}}$$

where A is a transition matrix. Aᵢⱼ represents the possibility of the transition from tag i to tag j. A is a trainable parameter. The training process of A is discussed below.

The aforementioned algorithms can be implemented using Python 3.7.2 with Tensor-Flow 1.13.1 framework.

The neural network is trained on a training dataset in order to be able to recognize operation entities and trigger entities from a sequence of words. The training dataset may be obtained from, for instance, student reports of an undergraduate physical-computing course. The training dataset may also be obtained from any source that contains natural language description of the operations and triggers of physical computing systems and the physical components used to realize the physical computing systems.

To prepare the training dataset, an original dataset, e.g. student reports, may be manually analyzed to label terms defining triggers (trigger entities) and terms defining operations (operation entities). The inventors have determined that a verb prior to a noun is more likely to represent a trigger entity or an operation entity with less ambiguity compared to a noun. Therefore, the above sentence may be labeled as follows:
“When the user<e1> swings</e1> the baton, a bird will<e2> sing</e2> a song.”

The pair of labels<e1> and </e1> indicates that the term “swing” defines a trigger. Similarly, the pair of labels<e2> and </e2> indicates that the term “sing” defines an operation.

In some circumstances, a user may envision a physical computing system having multiple triggers and/or operations. For instance, as shown in Table 1 below, the student of Case 2 designed a toy stick reacting to a button on the handle of the stick being pressed and the stick waving. In this case, both “press” and “wave” were labeled as triggers while both “played” and “blinked” were labeled as operations. In another example, as shown below in Case 4 of Table 1, the term “opening” was labeled as a trigger and the terms “turn on”, “turning around”, and “plays” were labeled as operations.

In some circumstances, a trigger or an operation may be represented by a noun rather than a verb. For instance, a student described a physical computing concept as follows:
“The light and music will become weird and spooky when another sensor has sensed someone passes through.”

For such a description, terms that are not verbs may be labeled as operations. In this instance, the nouns “light” and “music” were labeled as operations and the phrasal verb “passes through” were labeled as a trigger.

Table 1 below shows further examples of labeled sentences taken from the student reports of the undergraduate physical-computing course.

The labeled sentences may be rephrased for data augmentation, resulting in a larger training set for training the neural network.

To train the neural network employed by entity extractor 108, the transition matrix A can be initialized with zeros. A SoftMax possibility is computed by the following equation:

$$P ( Y \vert X ) = \frac{{e}^{score ( X , Y )}}{{\sum }_{\tilde{Y} ∈ {Y}_{X}} {e}^{score ( X , \tilde{Y} )}}$$

where Y_{X} represents all possible predicted sequences. \tilde{Y} denotes an instance of predicted Y during iteration.

TABLE 1

| Categories | Count | Example | |
|---|---|---|---|
| One input | 108 | When the user <e1>swing</e1> the | Case 1 |
| to one | | baton, a bird will <e2>sing</e2> a song. | |
| output | | | |
| Multiple | 9 | When we <e1>press</e1> the button | Case 2 |
| input to | | on the handle and <e1>wave</e1> | |
| multiple | | the stick at the same time, music | |
| outputs | | will be <e2>played</e2> and the | |
| | | LED light bulb will be <e2>blinked</e2> | |
| | | according to the rhythm of the music. | |
| Multiple | 9 | Out invention can <e1>release</e1> water | Case 3 |
| input to | | regularly to water the plant and | |
| one output | | <e1>make</e1>, a sound once the | |
| | | moisture sensor <e2>detect</e2> the | |
| | | humidity of the plant reached the | |
| | | point we have set. | |
| One input | 28 | After <e1>opening</e1> the music box, | Case 4 |
| to multiple | | the lights inside the box <e2>turn | |
| outputs | | on</e2>, the barbie doll head is | |
| | | <e2>turning around</e2> and the horror | |
| | | music <e2>plays</e2>. | |

During training, a log-likelihood of the ground truth tag sequence as defined below is maximized:

$$log ( P ( Y \vert X ) ) = score ( X , Y ) - log ( {\sum }_{\tilde{Y} ∈ {Y}_{X}} {e}^{score ( X , \tilde{Y} )} )$$

The network can be optimized using an optimizer for training deep learning models. For example, an Adam optimizer (β1=0.9, β2=0.999) with learning rate of 10⁻⁵ can be used.

Dropout technique may be applied to drop randomly selected neurons during training to avoid over-fitting. For example, the dropout technique discussed in N. Srivastava, G. Hinton, A. Krizhevsky, I. Sutskever, R. Salakhutdinov, 1005 Dropout: A simple way to prevent neural networks from overfitting, Journal 1006 of Machine Learning Research 15 (2014) 1929-1958 can be applied to the training process discussed above with a dropout rate of 0.5.

During predicting, the CRF layer outputs a sequence that has a maximum score computed by:

Y*=\tilde{Y}∈Y_{X}argmaxs(X,\tilde{Y})

where Y_{X} represents all possible sequences, \tilde{Y} denotes an instance of Y during iteration, argmaxs is the Augmax function.

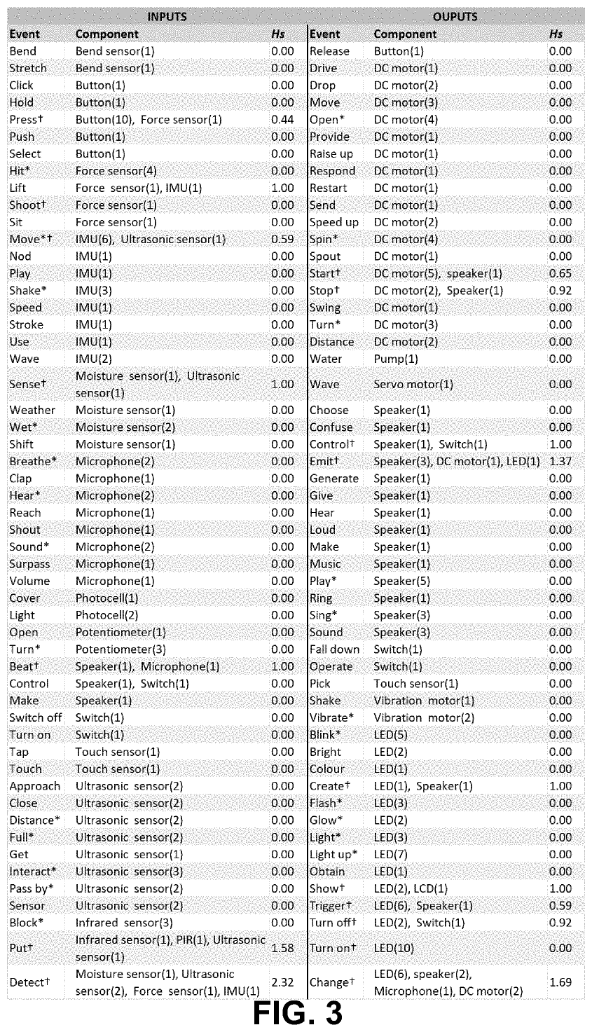

Each trigger or operation may be correlated with one or more components for implementing the trigger or operation. Such components may be identified by the manual analysis of the student reports or otherwise determined. The trigger entities and operation entities extracted from the original dataset and the components correlated thereto are stored in the data store 20 for component retrieval. For example, in Case 1 listed in Table 1 above, the student used an Inertial Measurement Unit (IMU) to detect the “swing” movement, and a buzzer to play the music. Therefore, the IMU may be determined to be correlated with trigger entity “swing.” The data store 20 is accordingly populated with data identifying or associated with IMU such that IMU is retrievable using the term “swing.” Similarly, the component “speaker” may be determined to be correlated with operation entity “sing”. The data store 20 is accordingly populated with data identifying or associated with speaker such that speaker is retrievable using the term “sing.” In one example, the data store 20 comprises a lookup table as shown in FIG. 3. The data store 20 may also comprise a table for storing usage and wiring rules of each identified component. The usage and wiring rules may also be retrievable using the term correlated with the component. A predefined program code for running on a programming environment to configure the component may also be stored in data store 20. The usage, wiring rules, and program code stored in data store 20 for a component may be retrievable using the term associated with the component. Each wiring rule is stored as an individual entry in a stack structure so that a step-by-step wiring instruction may be provided to the user.

Terms that are similar in meaning may be stored as a single entry. Various forms taken by the same term may also be stored as a single entry. Some terms and phrasal verbs identified could be general in the sense that they may correlate with multiple components. For instance, the term “detect” may correlate with different components depending on the object of the term. In Case 3 shown above, the student wanted to make an automatic irrigation system that can automatically water a plant in response to low moisture level in the soil (e.g., being less than a threshold). The terms “detect” and “release” in Case 3 were labeled as trigger entity and operation entity, respectively, while the terms “detect” and “release” could be correlated with several components. In this case, as the student implemented, the component used to realize the action “release” was a “water pump” as the object of release was “water”, while the component used to realize the action “detect” was “humidity sensor” as the object of detection was “humidity”. Despite the above discussed labeling rules, ambiguity may still occur with certain terms. To quantify ambiguity, a Shannon entropy is computed for each event (trigger or operation) as follows:

$${H}_{s} = {{\sum }_{i = 1}}^{n} {p}_{i} {I}_{i} = - {{\sum }_{i = 1}}^{n} {p}_{i} {log}_{2} {p}_{i}$$

where pᵢ is the probability of a component to occur under event i, n is the total number of components. I is an information function of event i with probability pᵢ, defined as log₂ pᵢ.

In the example of the present disclosure, the entropy values for all the stored events are as shown in FIG. 3. If an event has a Shannon Entropy that equals to 0, then the event is unambiguous. The greater the entropy score is, the more ambiguous the event is. A threshold value may be set such that any event having a Shannon entropy that is greater than the threshold value may be marked as an ambiguous event. In one example, an event with a Shannon entropy greater than 0.5 may be marked as an ambiguous event. The method of retrieving components based on event will be described in more detail below.

The data store 20 may also store a predefined system program code for running on a programming environment to configure the composed system.

Referring still to FIG. 2, the response engine 120 is in data communication with the data store 20 and a circuit simulator program (not shown). The response engine 120 is configured to generate a response either directly or via the circuit stimulator program.

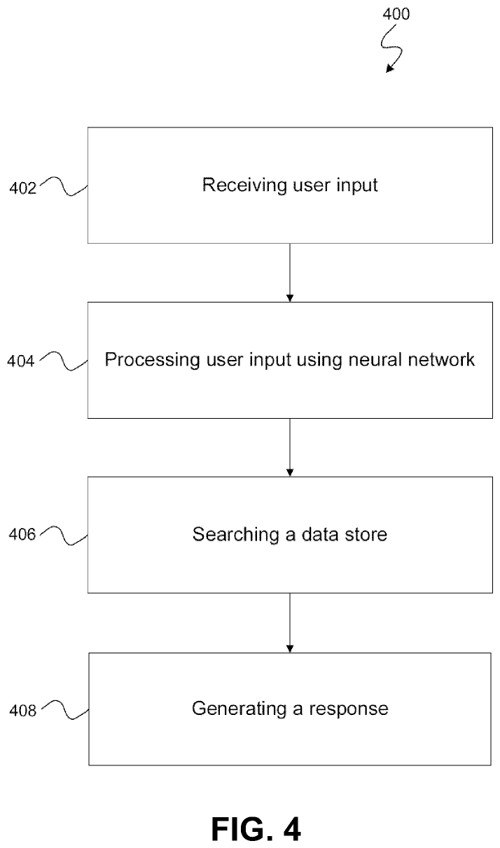

Referring now to FIG. 4, a flowchart of a method 400, performed by the application 10, of composing a system for performing a task is shown.

At step 402, the application 10 receives a user input comprising a sequence of words.

At step 404, the application 10 feeds the user input to the natural language processor 100 for processing using a neural network for entity recognition to identify a term defining an event from the sequence of words.

At step 406, application 10 searches data store 20 using the identified term to determine a component for the system.

The processing performed by application 10 at step 404 may identify one or more further terms defining one or more further events, if present in the user input. Using the one or more further terms, one or more further components may be determined at step 406 for the system by the search. The processing performed by application 10 may identify at least one term defining a trigger and at least one term defining an operation. The trigger and operation defined by the identified terms may have a causal relationship.

The searching conducted based on the identified term (i.e., search term) comprises searching for the most similar match to be used as the search term for component retrieval. The similarity between the search term and the events stored in the data store 20 may be measured by a word distance computed using WordNet. If the identified term defines an ambiguous event (i.e., having a Shannon entropy of less than 0.5), then the most similar unambiguous match is searched for. In particular, the searching comprises computing the word distance between the object of the search term and each of the objects of the ambiguous events stored in the data store 20, and sorting the events based on the word distances in ascendant order. The first event with the Shannon Entropy smaller than 0.5 (i.e. non-ambiguous event) is determined to be the search term for component retrieval.

At step 408, the application 10 generates a response based on the determined component.

In one arrangement, the response is directly presented to the user via the user interface 140. In another arrangement, a portion of the response is presented via the circuit simulator program and another portion of the response is presented to the user via the user interface 140.

The response may comprise a graphical representation of the system, for example, a circuit diagram, on a canvas provided in a Graphical User Interface (GUI). The canvas may be provided by the circuit simulator program. The graphical representation of each component and the component interconnection, e.g., the wires, may be obtained from a component library of the circuit simulator program.

Additionally or optionally, the response may comprise wiring instructions for instructing a user to physically construct the system using the determined components. The wiring instructions may comprise wiring rules for each component retrieved from the data store 20. The application 10 may use an optimized A* search algorithm to manage pins and dynamically distribute and wire all electronic components on the canvas to reduce overlapping.

The circuit diagram may be semi-completed when only one component is determined and can be updated as more components are determined. For example, when the application 10 determines a further component to be added to the system, an icon representing the further component retrieved, for example, from the circuit simulator program, is added to the canvas and wired based on the wiring rules of the further component retrieved from data store 20. The wiring rules in respect of that particular component is added to the already displayed wiring instructions. After each addition, the displayed graphical representation and wiring instructions are updated to reflect the addition. A copy of the updated graphical representation and wiring instructions may be saved to allow restoration of a previous view when further additions occur. In other words, a user can track back to any previous step for a clearer view of wires.

Additionally or optionally, the response may comprise program codes for running on a programming environment, for example, Arduino Software, to configure the components and/or the system when connected to an Arduino board, for example. The program codes may be predefined and retrieved from data store 20 based on the identified term. The processing performed by application 10 may identify a term defining an attribute. The identified term may be used, for instance, to determine the brightness for a light as “very bright” or “dim”, or to define a distance threshold detected by a proximity sensor as “closed” or “far”, etc. An attribute is typically represented by an adjective or an adverb. The adjectives and adverbs may be identified from the user input by the POS tagger. For example, if a user would like to have a light to be very bright or dim, the term “bright” or “dim” is identified as attribute. A plurality of attributes may be predefined for a configurable component such as light, speaker, vibrator. The response engine 120 is able to assign the attribute that matches the identified attribute term when generating the program code associated with the component.

Additionally or optionally, the response may comprises messages in order to facilitate users' understanding of the generated system. A number of forms of message responses may be predefined for different types of user input.

In one example, the response may comprise a confirmation of the completion of the process of composing. For instance, a message such as “According to your description<e>, I suggest using<c> as the trigger/operation component” may be displayed, where e denotes the extracted user input event and c denotes the determined electronic component. The message may be displayed while the application 10 is generating the system diagram or setting the attributes.

In some circumstances, the user input may make reference to a component. The referenced component may be identified by the processing and compared with the component determined by the searching. If the referenced component does not match the component determined by the searching, a message, such as “You should use<c1> instead of <c2> to detect<e>.”) may be displayed to recommend the determined component to the user, where c1 denotes the component determined by the searching, c2 denotes the component identified from the user input, and e denotes is the extracted event.

In some embodiments, the user input may be analyzed using the user intent recognizer 104 to determine whether the user input is related to a query about a specific component or a request to construct a system. If the user intent recognizer 104 determines that the user intent is a query about a specific component, the response engine 120 retrieves information related to the queried component and forms a response including the information for presenting to the user.

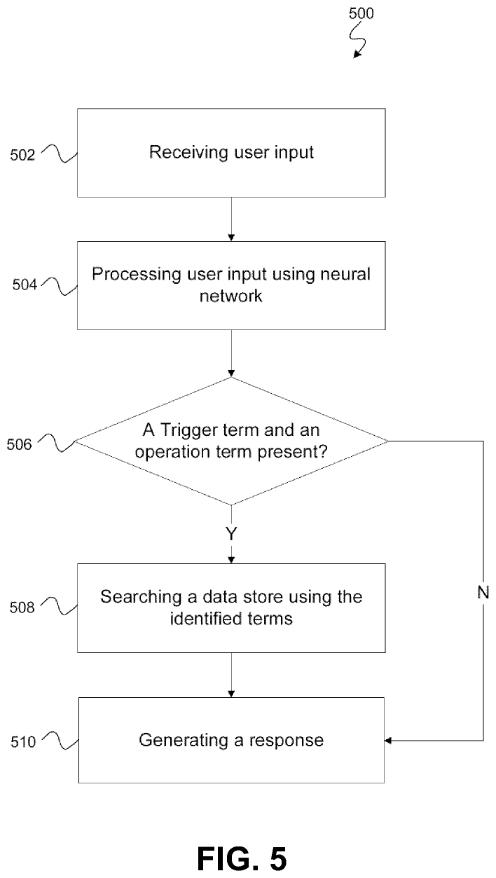

In some embodiments, the response engine 120 checks the completeness of the system as discussed below with reference to FIG. 5.

Referring to FIG. 5, a flowchart of a method 500 performed by the application 10 for composing a system for performing a task is shown.

At step 502, the application 10 receives a user input comprising a sequence of words.

At step 504, the application 10 feeds the user input to the natural language processor 100 for processing using a neural network for entity recognition to identify a term defining an operation and a term defining a trigger from the sequence of words.

At step 506, application 10 determines whether a complete system has been defined. The determination may comprise checking whether a term defining an operation and a term defining a trigger have been identified. In response to determining that a complete system has been defined, the method 500 proceeds to step 508. In response to determining that a complete system has not been defined, the method 500 proceeds to step 510.

At step 508, the application 10 searches data store 20 using the identified terms to determine an operation component and a trigger component for the system.

At step 510, the application 10 generates a response to the user.

If the application 10 determines at step 506 that a complete system has not been defined, the application generates a response comprising a message to the user requesting input of the missing description. For example, if the application 10 only identifies a term defining an operation at step 504, the message may be, for example, “It seems like your system lacks a trigger.”

On the other hand, if the application 10 determines at step 506 that a complete system has been defined, the application generates at step 510 a response comprising at least one of a graphical representation, wiring instructions, program codes, as described above with respect to method 400. For example, if the application 10 identifies a term defining an operation and a term defining a trigger at step 504, the application 10 responds by displaying a graphical representation of the system comprising an operation component and a trigger component determined at step 508, as well as corresponding wiring instructions and program codes.

The determination performed by the application 10 at step 506 may comprise checking whether the user input comprises a term defining an attribute. If the user input does not comprise such a term, the response engine 120 generates a response in the form of a question to ask the user to define an attribute for the identified event. A number of follow up questions may be predefined. For example, a follow up question may be “How many<c> would you like to have?” to get the quantity of the retrieved component c from the user. In another example, a follow up question may be “How would you like the trigger/operation<e> to be?” to ask the user to further define the attribute of the event e. In yet another example, a follow up question may be “It seems like that your system is missing the trigger/operation part. Would you like to provide more information?” Based on the information provided by the user, the response engine 120 may generate program codes specific to the defined attribute.

FIGS. 6A and 6B depict a general-purpose computer system 600, upon which the various arrangements described can be practiced.

As seen in FIG. 6A, the computer system 600 includes: a computer module 601; input devices such as a keyboard 602, a mouse pointer device 603, a scanner 626, a camera 627, and a microphone 680; and output devices including a printer 615, a display device 614 and loudspeakers 617. An external Modulator-Demodulator (Modem) transceiver device 616 may be used by the computer module 601 for communicating to and from a communications network 620 via a connection 621. The communications network 620 may be a wide-area network (WAN), such as the Internet, a cellular telecommunications network, or a private WAN. Where the connection 621 is a telephone line, the modem 616 may be a traditional “dial-up” modem. Alternatively, where the connection 621 is a high capacity (e.g., cable) connection, the modem 616 may be a broadband modem. A wireless modem may also be used for wireless connection to the communications network 620.

The computer module 601 typically includes at least one processor unit 605, and a memory unit 606. For example, the memory unit 606 may have semiconductor random access memory (RAM) and semiconductor read only memory (ROM). The computer module 601 also includes an number of input/output (I/O) interfaces including: an audio-video interface 607 that couples to the video display 614, loudspeakers 617 and microphone 680; an I/O interface 613 that couples to the keyboard 602, mouse 603, scanner 626, camera 627 and optionally a joystick or other human interface device (not illustrated); and an interface 608 for the external modem 616 and printer 615. In some implementations, the modem 616 may be incorporated within the computer module 601, for example within the interface 608. The computer module 601 also has a local network interface 611, which permits coupling of the computer system 600 via a connection 623 to a local-area communications network 622, known as a Local Area Network (LAN). As illustrated in FIG. 6A, the local communications network 622 may also couple to the wide network 620 via a connection 624, which would typically include a so-called “firewall” device or device of similar functionality. The local network interface 611 may comprise an Ethernet circuit card, a Bluetooth® wireless arrangement or an IEEE 802.11 wireless arrangement; however, numerous other types of interfaces may be practiced for the interface 611.

The I/O interfaces 608 and 613 may afford either or both of serial and parallel connectivity, the former typically being implemented according to the Universal Serial Bus (USB) standards and having corresponding USB connectors (not illustrated). Storage devices 609 are provided and typically include a hard disk drive (HDD) 610. Other storage devices such as a floppy disk drive and a magnetic tape drive (not illustrated) may also be used. An optical disk drive 612 is typically provided to act as a non-volatile source of data. Portable memory devices, such optical disks (e.g., CD-ROM, DVD, Blu-ray Disc™), USB-RAM, portable, external hard drives, and floppy disks, for example, may be used as appropriate sources of data to the system 600.

The components 605 to 613 of the computer module 601 typically communicate via an interconnected bus 604 and in a manner that results in a conventional mode of operation of the computer system 600 known to those in the relevant art. For example, the processor 605 is coupled to the system bus 604 using a connection 618. Likewise, the memory 606 and optical disk drive 612 are coupled to the system bus 604 by connections 619. Examples of computers on which the described arrangements can be practised include IBM-PC's and compatibles, Sun Sparcstations, Apple Mac™ or like computer systems.

The methods described above may be implemented using the computer system 600 wherein the processes of FIGS. 4 and 5 may be implemented as one or more software application programs 633 executable within the computer system 600. In particular, the steps of the above described methods of are effected by instructions 631 (see FIG. 6B) in the software 633 that are carried out within the computer system 600. The software instructions 631 may be formed as one or more code modules, each for performing one or more particular tasks. The software may also be divided into two separate parts, in which a first part and the corresponding code modules performs the methods and a second part and the corresponding code modules manage a user interface between the first part and the user.

The software may be stored in a computer readable medium, including the storage devices described below, for example. The software is loaded into the computer system 600 from the computer readable medium, and then executed by the computer system 600. A computer readable medium having such software or computer program recorded on the computer readable medium is a computer program product.

The software 633 is typically stored in the HDD 610 or the memory 606. The software is loaded into the computer system 600 from a computer readable medium, and executed by the computer system 600. Thus, for example, the software 633 may be stored on an optically readable disk storage medium (e.g., CD-ROM) 625 that is read by the optical disk drive 612. A computer readable medium having such software or computer program recorded on it is a computer program product.

In some instances, the application programs 633 may be supplied to the user encoded on one or more CD-ROMs 625 and read via the corresponding drive 612, or alternatively may be read by the user from the networks 620 or 622. Still further, the software can also be loaded into the computer system 600 from other computer readable media. Computer readable storage media refers to any non-transitory tangible storage medium that provides recorded instructions and/or data to the computer system 600 for execution and/or processing. Examples of such storage media include floppy disks, magnetic tape, CD-ROM, DVD, Blu-ray™ Disc, a hard disk drive, a ROM or integrated circuit, USB memory, a magneto-optical disk, or a computer readable card such as a PCMCIA card and the like, whether or not such devices are internal or external of the computer module 601. Examples of transitory or non-tangible computer readable transmission media that may also participate in the provision of software, application programs, instructions and/or data to the computer module 601 include radio or infra-red transmission channels as well as a network connection to another computer or networked device, and the Internet or Intranets including e-mail transmissions and information recorded on Websites and the like.

The second part of the application programs 633 and the corresponding code modules mentioned above may be executed to implement one or more graphical user interfaces (GUIs) to be rendered or otherwise represented upon the display 614. Through manipulation of typically the keyboard 602 and the mouse 603, a user of the computer system 600 and the application may manipulate the interface in a functionally adaptable manner to provide controlling commands and/or input to the applications associated with the GUI(s). Other forms of functionally adaptable user interfaces may also be implemented, such as an audio interface utilizing speech prompts output via the loudspeakers 617 and user voice commands input via the microphone 680.

FIG. 6B is a detailed schematic block diagram of the processor 605 and a “memory” 634. The memory 634 represents a logical aggregation of all the memory modules (including the HDD 609 and semiconductor memory 606) that can be accessed by the computer module 601 in FIG. 6A.

When the computer module 601 is initially powered up, a power-on self-test (POST) program 650 executes. The POST program 650 is typically stored in a ROM 649 of the semiconductor memory 606 of FIG. 6A. A hardware device such as the ROM 649 storing software is sometimes referred to as firmware. The POST program 650 examines hardware within the computer module 601 to ensure proper functioning and typically checks the processor 605, the memory 634 (609, 606), and a basic input-output systems software (BIOS) module 651, also typically stored in the ROM 649, for correct operation. Once the POST program 650 has run successfully, the BIOS 651 activates the hard disk drive 610 of FIG. 6A. Activation of the hard disk drive 610 causes a bootstrap loader program 652 that is resident on the hard disk drive 610 to execute via the processor 605. This loads an operating system 653 into the RAM memory 606, upon which the operating system 653 commences operation. The operating system 653 is a system level application, executable by the processor 605, to fulfil various high level functions, including processor management, memory management, device management, storage management, software application interface, and generic user interface.

The operating system 653 manages the memory 634 (609, 606) to ensure that each process or application running on the computer module 601 has sufficient memory in which to execute without colliding with memory allocated to another process. Furthermore, the different types of memory available in the system 600 of FIG. 6A must be used properly so that each process can run effectively. Accordingly, the aggregated memory 634 is not intended to illustrate how particular segments of memory are allocated (unless otherwise stated), but rather to provide a general view of the memory accessible by the computer system 600 and how such is used.

As shown in FIG. 6B, the processor 605 includes a number of functional modules including a control unit 639, an arithmetic logic unit (ALU) 640, and a local or internal memory 648, sometimes called a cache memory. The cache memory 648 typically includes a number of storage registers 644-646 in a register section. One or more internal busses 641 functionally interconnect these functional modules. The processor 605 typically also has one or more interfaces 642 for communicating with external devices via the system bus 604, using a connection 618. The memory 634 is coupled to the bus 604 using a connection 619.

The application program 633 includes a sequence of instructions 631 that may include conditional branch and loop instructions. The program 633 may also include data 632 which is used in execution of the program 633. The instructions 631 and the data 632 are stored in memory locations 628, 629, 630 and 635, 636, 637, respectively. Depending upon the relative size of the instructions 631 and the memory locations 628-630, a particular instruction may be stored in a single memory location as depicted by the instruction shown in the memory location 630. Alternately, an instruction may be segmented into a number of parts each of which is stored in a separate memory location, as depicted by the instruction segments shown in the memory locations 628 and 629.

In general, the processor 605 is given a set of instructions which are executed therein. The processor 605 waits for a subsequent input, to which the processor 605 reacts to by executing another set of instructions. Each input may be provided from one or more of a number of sources, including data generated by one or more of the input devices 602, 603, data received from an external source across one of the networks 620, 602, data retrieved from one of the storage devices 606, 609 or data retrieved from a storage medium 625 inserted into the corresponding reader 612, all depicted in FIG. 6A. The execution of a set of the instructions may in some cases result in output of data. Execution may also involve storing data or variables to the memory 634.

The disclosed arrangements use input variables 654, which are stored in the memory 634 in corresponding memory locations 655, 656, 657. The arrangements produce output variables 661, which are stored in the memory 634 in corresponding memory locations 662, 663, 664. Intermediate variables 658 may be stored in memory locations 659, 660, 666 and 667.

Referring to the processor 605 of FIG. 6B, the registers 644, 645, 646, the arithmetic logic unit (ALU) 640, and the control unit 639 work together to perform sequences of micro-operations needed to perform “fetch, decode, and execute” cycles for every instruction in the instruction set making up the program 633. Each fetch, decode, and execute cycle comprises:

a fetch operation, which fetches or reads an instruction 631 from a memory location 628, 629, 630;

a decode operation in which the control unit 639 determines which instruction has been fetched; and

an execute operation in which the control unit 639 and/or the ALU 640 execute the instruction.

Thereafter, a further fetch, decode, and execute cycle for the next instruction may be executed. Similarly, a store cycle may be performed by which the control unit 639 stores or writes a value to a memory location 632.

Each step or sub-process in the processes of FIGS. 4 and 5 is associated with one or more segments of the program 633 and is performed by the register section 644, 645, 647, the ALU 640, and the control unit 639 in the processor 605 working together to perform the fetch, decode, and execute cycles for every instruction in the instruction set for the noted segments of the program 633.

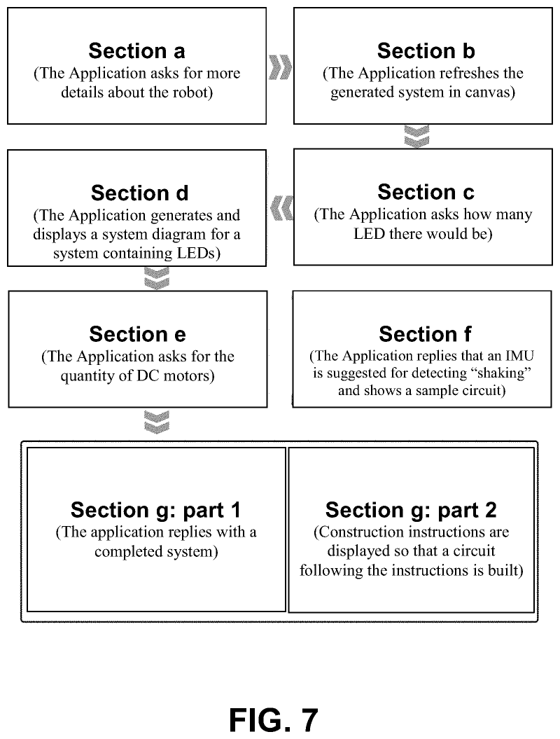

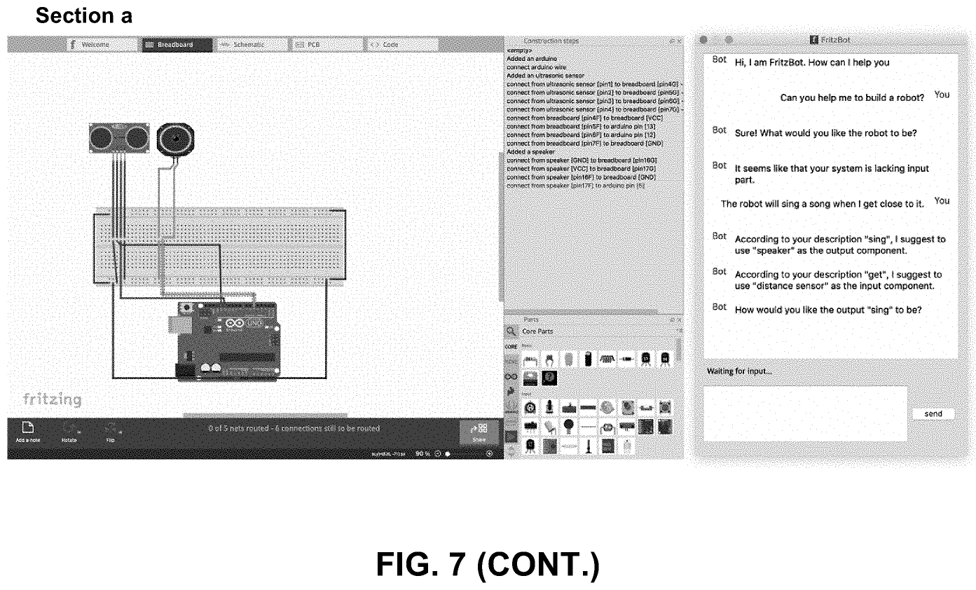

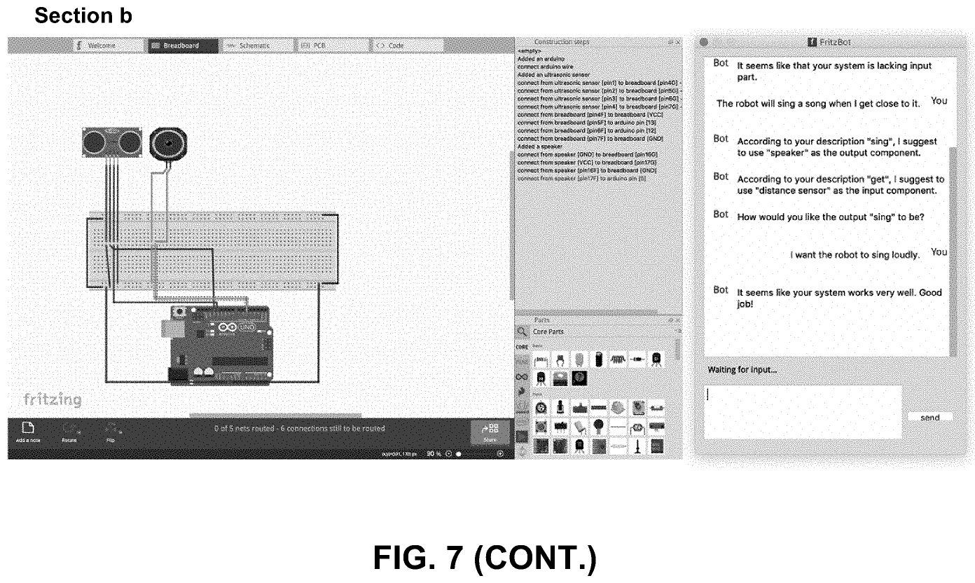

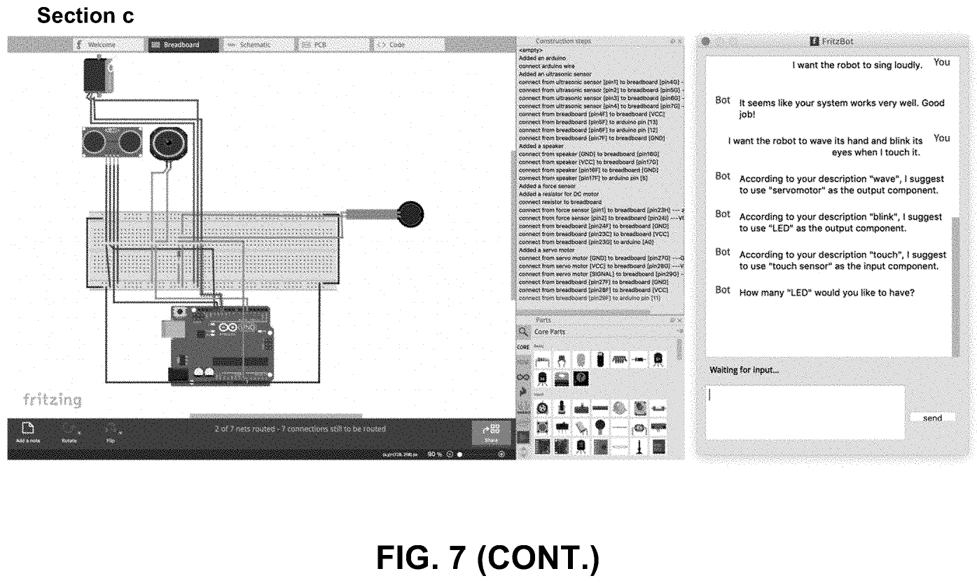

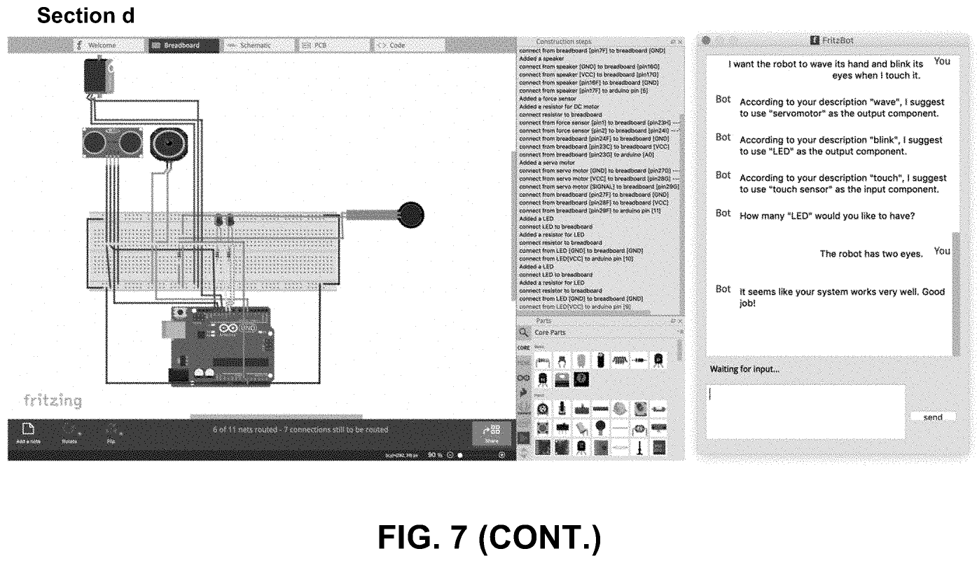

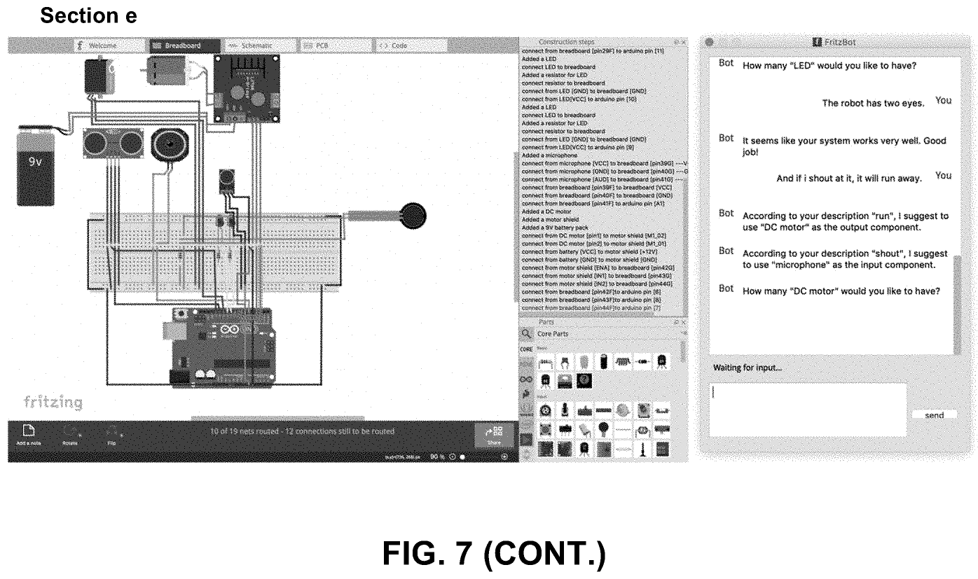

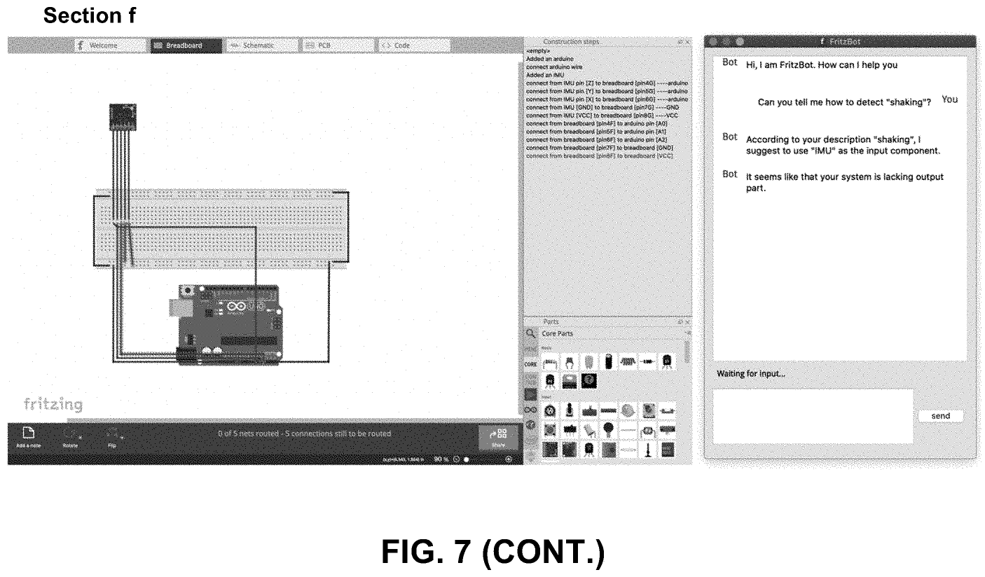

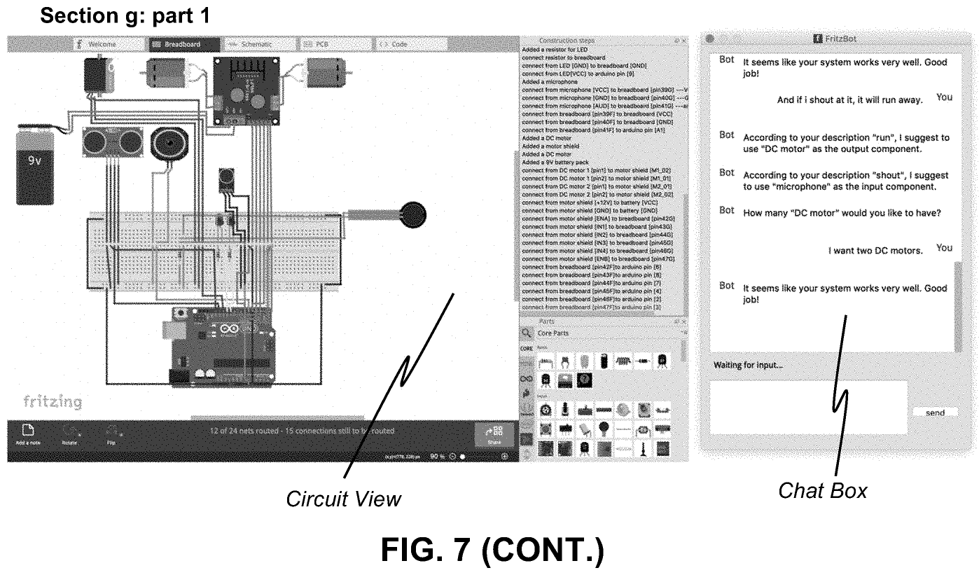

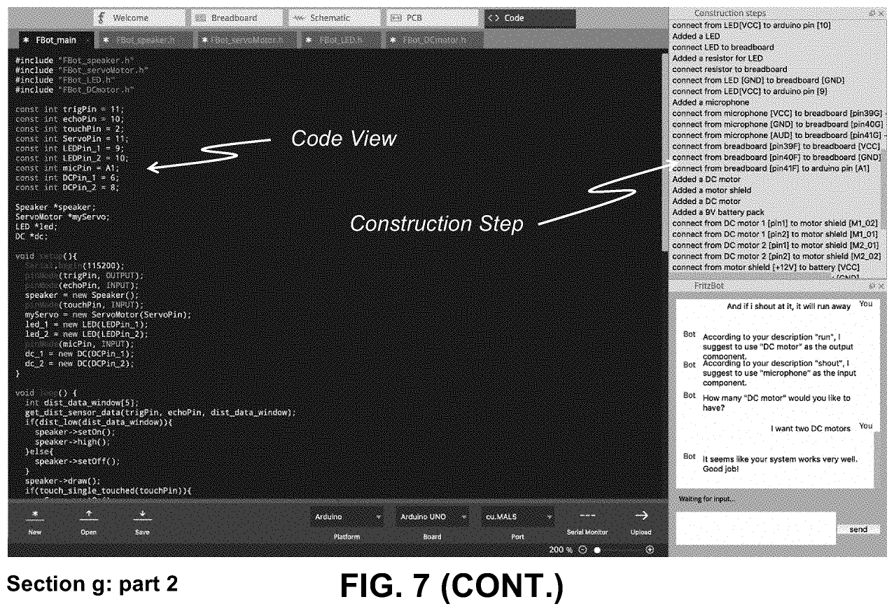

A use case of the present invention will now be described with reference to FIG. 7.

Alan is a bachelor student majored in design. He would like to build a smart robot that is able to react to different human activities as follow: 1) the robot is able to sing a song loudly when there is someone getting close thereto; 2) the robot is able to wave a hand and blink eyes while being touched; 3) the robot is able to run away if getting shouted at. After formulating this idea, Alan installs the application 10 on his laptop and starts to create a physical-computing prototype with the aid of the application.

Once Alan enters that he would like to make a robot, the application 10 replies him to ask for more details about the robot, as shown in FIG. 7, section a. Alan describes the first function by inputting a sentence “The robot will sing a song when we get close to it”. In response to the input, application 10 generates a semi-completed system shown in a canvas. In addition, the application 10 asks Alan for more detailed parameters for the “sing” event. Alan inputs a further sentence “I want the robot to sing loudly”. In response to the further sentence, the application 10 refreshes the generated system in the canvas, as shown in FIG. 7, section b.

Alan would like the robot to achieve a second function, so he enters yet a further sentence “I want the robot to wave its hand and blink its eyes when I touch it”. In response to the yet further sentence, the application responds with a suggestion to use a servo motor and LED for the wave event and the blink event respectively. The Application asks Alan how many LED he would like to have, as shown in FIG. 7, section c. Alan replies with “The robot has two eyes”. In response to the reply, the application 10 generates and displays a system diagram for a system containing two LEDs, as shown in FIG. 7, section d.

Lastly, Alan enters a sentence “And if I shout at it, it will run away”. The application 10 responds with a suggestion that Alan should use a microphone to detect the “shout at” event and DC motors for “run away”. The application 10 then asks Alan for the quantity of DC motors, as shown in FIG. 7, section e. Alan decides that the robot should have two wheels, and enters a sentence “I want two DC motors”. The application 10 replies with a completed system, as shown in FIG. 7, section g. Construction instructions are displayed so that Alan may build a circuit following the instructions, as shown in FIG. 7, section g. Alan is able to restore previous views for a clearer view of wires. After completing the constructions of the circuit, Alan connects the Arduino UNO to his laptop, navigates to the code generated by application 10, and uploads the code the Arduino UNO, as shown in FIG. 7, section g.

After prototyping the robot, Alan wants to add a function to the robot. He would like the robot to know if someone is shaking its hand. However, Alan does not know how to detect the “shaking” event. Alan therefore inputs a sentence “Can you tell me how to detect ‘shaking’?” in application 10. Application 10 replies that an IMU is suggested for detecting “shaking” and shows a sample circuit, as shown in FIG. 7, section f.

While some of the existing physical-computing prototyping platforms may also provide wiring guidance for the electrical components used in the example above, a user like Alan may still encounter difficulty in determining what components should be used without prior knowledge of the components. For example, the user may not have the knowledge as to which sensor should be used to detect the event of “getting close to the robot”. With the present invention, a user need not have sophisticated knowledge to construct a system, for example, a physical computing system. The present invention is able to understand user input in natural language and thereby facilitates the design and creation of physical computing systems.

Whilst the invention has been described with reference to a physical computing system, it will be appreciated that the invention is not limited to this application and may be used in designing non-physical computing systems.

Although specific embodiments of the invention are illustrated and described herein, it will be appreciated by those of ordinary skill in the art that a variety of alternative and/or equivalent implementations exist. It should be appreciated that the exemplary embodiment or exemplary embodiments are examples only and are not intended to limit the scope, applicability, or configuration in any way. Rather, the foregoing summary and detailed description will provide those skilled in the art with a convenient road map for implementing at least one exemplary embodiment, it being understood that various changes may be made in the function and arrangement of elemeDnts described in an exemplary embodiment without departing from the scope as set forth in the appended claims and their legal equivalents. Generally, this application is intended to cover any adaptations or variations of the specific embodiments discussed herein.

It will also be appreciated that in this document the terms “comprise”, “comprising”, “include”, “including”, “contain”, “containing”, “have”, “having”, and any variations thereof, are intended to be understood in an inclusive (i.e. non-exclusive) sense, such that the process, method, device, apparatus or system described herein is not limited to those features or parts or elements or steps recited but may include other elements, features, parts or steps not expressly listed or inherent to such process, method, article, or apparatus. Furthermore, the terms “a” and “an” used herein are intended to be understood as meaning one or more unless explicitly stated otherwise. Moreover, the terms “first”, “second”, etc. are used merely as labels, and are not intended to impose numerical requirements on or to establish a certain ranking of importance of their objects.

1. A computer-implemented method of composing, using natural language processing, a system for performing a task, the method comprising:
receiving a user input comprising a sequence of words;
processing the user input using a neural network for entity recognition to identify, from the sequence of words, a term defining an event; and
searching a data store having stored therein data indicative of a plurality of components, using the identified term, to determine a component for the system.

2. The computer-implemented method of claim 1, wherein the processing comprises identifying a further term defining a further event, and the searching comprises determining a further component for the system using the further term.

3. The computer-implemented method of claim 2, wherein the event and the further event have a causal relationship.

4. The computer-implemented method of claim 2 further comprising generating a response based on the determined component.

5. The computer-implemented method of claim 4, wherein the response comprises a graphical representation of the system.

6. The computer-implemented method of claim 4, wherein the response comprises wiring instructions for guiding a user to physically construct the system.

7. The computer-implemented method of claim 4, wherein the response comprises a program code for running on a programming environment to configure the component.

8. The computer-implemented method of claim 4, wherein the response comprises a program code for running on a programming environment to configure the system.

9. The computer-implemented method of claim 1, wherein the neural network comprises a Bidirectional Long Short-Term Memory (BiLSTM) layer.

10. The computer-implemented method of claim 9, wherein the neural network comprises a Conditional Random Fields (CRF) layer.

11. The computer-implemented method of claim 1, wherein the term is a verb before a noun.

12. The computer-implemented method of claim 1, wherein the term is a noun.

13. The computer-implemented method of claim 1, wherein the system is a physical computing system.

14. The computer-implemented method of claim 1, the processing comprises identifying a further term defining an attribute of the event.
